(19) United States
(12) Patent Application Publication
(10) Pub. No.: US 2022/0389562 A1
(43) Pub. Date: Dec. 8, 2022

(54) OPTICAL COATING WITH LOW REFRACTIVE INDEX FILM DEPOSITION

(71) Applicant: Meta Platforms Technologies, LLC, Menlo Park, CA (US)

(72) Inventors: Paul Murray LeFebvre, Brookings, OR (US); Weihua Gao, Rancho Santa Margarita, CA (US); Christopher Yuan Ting Liao, Seattle, WA (US)

(21) Appl. No.: 17/827,407

(22) Filed: May 27, 2022

Related U.S. Application Data
(60) Provisional application No. 63/197,098, filed on Jun. 4, 2021.

(51) Int. Cl. C23C 14/10; G02B 1/115; C23C 14/24

(52) U.S. Cl. CPC C23C 14/10; G02B 1/115; C23C 14/24

(57) ABSTRACT

A method of forming a low reflectivity coating on an optical surface for wide angle of incidence is provided. The method includes depositing a low refractive index layer of material on a stack of dielectric layers, depositing a hydrophobic compatible material on the stack of dielectric layers, forming a blend interface layer on the stack of dielectric layers, the blend interface layer including a portion of the low refractive index layer of material and a portion of the hydrophobic compatible material, and depositing a hydrophobic layer of material adjacent to the blend interface layer. A physical vapor deposition chamber to perform the above method is also provided.

### CROSS-REFERENCE TO RELATED APPLICATIONS

The present disclosure is related and claims priority under 35 USC 119(e) to U.S. Provisional Patent Application No. 63/197,098, entitled OPTICAL COATING WITH LOW REFRACTIVE INDEX FILM DEPOSITION, filed on Jun. 4, 2021, to Paul M. LEFEBVRE, et al., the contents of which are herein incorporated by reference in their entirety, for all purposes.

### BACKGROUND

### Field

The present disclosure is related to thin-film anti-reflection coatings (ARCs) used in optical or ophthalmic applications. More specifically, the present disclosure is related to thin-film anti-reflection coatings for wide angle, low reflectance applications.

### Art Status

Typical thin-film coating techniques combine two or more alternating layers of materials having high and low index of refraction. For design purposes, it is desirable to have a wide difference in the index of refraction of two materials. To avoid using very high index of refraction materials (which may be opaque and reduce transmittance in the visible wavelength domain from about 400 nm to about 750 nm), it is desirable to deposit material layers having a low index of refraction combined with material layers having a higher index of refraction. However, depositing low index of refraction layers is a challenging task, especially considering compatibility with the substrate and the other material layers deposited on top.

### BRIEF DESCRIPTION OF THE DRAWINGS

FIG. 1 illustrates a configuration for physical vapor deposition (PVD), including relevant parameters, according to some embodiments.

FIGS. 2A-2C illustrate PVD chambers configured for providing low index of refraction optical coatings for low reflectance at high angle of incidence on arbitrary optical surfaces, according to some embodiments.

FIG. 3 illustrates a cross section of a multilayer stack of dielectric layers having alternating high/low index of refraction, according to some embodiments.

FIG. 4 illustrates a cross section of a multilayer stack of dielectric layers having alternating high/low index of refraction, according to some embodiments.

FIG. 5 illustrates a composition plot of a blend interface in a multilayer stack, according to some embodiments.

FIG. 6 illustrates a reflectance plot at a wide angle of incidence for different dielectric materials, including a low-density magnesium fluoride (MgF₂) layer, according to some embodiments.

FIG. 7 is a flow chart illustrating steps in a method of forming a multilayer dielectric stack for anti-reflection coating of optical surfaces, according to some embodiments.

FIG. 8 is a flow chart illustrating steps in a method of forming a wide-angle, low-reflection coating on an optical surface, according to some embodiments.

FIG. 9 is a flow chart illustrating steps in a method for depositing a dielectric layer with a low index of refraction on an optical surface, according to some embodiments.

FIG. 10 is a block diagram illustrating an exemplary computer system with which the devices of FIGS. 1 and 2A-2C, and the methods of FIGS. 7-9 can be implemented, according to some embodiments.

In the figures, elements having same or similar reference numbers are assumed to have same or similar attributes and features, unless explicitly stated otherwise.

### SUMMARY

In a first embodiment, a method includes depositing a low refractive index layer of material on a stack of dielectric layers, and depositing a hydrophobic compatible material on the stack of dielectric layers. The method also includes forming a blend interface layer on the stack of dielectric layers, the blend interface layer including a portion of the low refractive index layer of material and a portion of the hydrophobic compatible material, and depositing a hydrophobic layer of material adjacent to the blend interface layer.

In a second embodiment, a method includes adjusting a pressure of a background gas in a deposition chamber to reduce a deposition energy of a dielectric material on a stack of dielectric layers. The method also includes depositing a layer of the dielectric material on the stack of dielectric layers, and depositing a hydrophobic layer of material adjacent to the layer of the dielectric material.

In a third embodiment, a method includes adjusting a tilt angle of a stack of dielectric layers relative to a material source in a deposition chamber to reduce a deposition density, wherein the material source is configured to provide a first dielectric material. The method also includes depositing a layer of the first dielectric material on the stack of dielectric layers, and depositing a hydrophobic layer of material adjacent to the layer of the first dielectric material.

In yet other embodiments, a system includes a first means to store instructions and a second means to execute the instructions and cause the system to perform a method, including adjusting a tilt angle of a stack of dielectric layers relative to a material source in a deposition chamber to reduce a deposition density, wherein the material source is configured to provide a first dielectric material, depositing a layer of the first dielectric material on the stack of dielectric layers, and depositing a hydrophobic layer of material adjacent to the layer of the first dielectric material.

### DETAILED DESCRIPTION

In the following detailed description, numerous specific details are set forth to provide a full understanding of the present disclosure. It will be apparent, however, to one ordinarily skilled in the art, that the embodiments of the present disclosure may be practiced without some of these specific details. In other instances, well-known structures and techniques have not been shown in detail so as not to obscure the disclosure. Embodiments in the present disclosure may include features, components, structures, and processes as disclosed herein.

This disclosure relates to thin-film anti-reflection coatings (ARCs) used in optical or ophthalmic applications, where high angle and low reflectance in the visible wavelength domain (e.g., from about 400 nm to about 750 nm) is desirable. These coatings are typically composed of dielectric layers (e.g., inorganic compounds) deposited by physical vapor deposition (PVD) techniques such as plasma-enhanced, sputtering, ion beam or electron beam enhanced deposition, and the like. Multilayer dielectric stacks consistent with the present disclosure may include from a few (e.g., four—4—) to as many as thirty (30) or more layers, or even more (100+).

In current practice, dielectric ARCs designed for minimum visible reflectance can suffer from high reflection levels as the angle of incidence (AOI) increases above 30-45 degrees. In multilayer stacks of dielectric layers, a combination of optical thickness shift of the individual layers and phase contrast, may drive reflectance levels as high as 30% near 75 degrees AOI. This is a hindrance for optical and ophthalmic applications involving optical components and surfaces having complex geometries configured for wide field of view (FOV) imaging in portable/wearable devices. The wide FOV imaging implies that the optical surfaces will desirably operate at high AOI. The complex geometries and mobility are typically achieved using lightweight, moldable materials, such as plastic, which are difficult to handle due to the environmental conditions typically found in PVD chambers (e.g., high temperatures and the like).

To resolve the above problem, it is desirable to have PVD techniques capable of handling low index of refraction materials, e.g., magnesium fluoride (MgF₂), for different substrates and geometries. However, magnesium fluoride coatings should desirably be durable and pass reliability testing when deposited at relatively low temperature on plastic substrates. However, current PVD techniques lack the ability to use magnesium fluoride for ARCs on plastic. For example, thick magnesium fluoride layers tend to develop tensile stress that may be unsustainable beyond a certain threshold. Accordingly, some embodiments as disclosed herein provide mechanisms and techniques to deposit porous layers of magnesium fluoride on a dielectric stack, which further reduces the refractive index. Additionally, porous layers provide a relief for the tensile stress developed by magnesium fluoride, desirably enlarging the thickness threshold of magnesium fluoride layers available for use and design.

It is also desirable that the outer layer of the ARC adheres to functional coatings capping the multilayer dielectric stack. For example, in some embodiments, a hydrophobic layer (e.g., a polymer or some other organic material) may be applied as capping layers to improve the cleaning ability of the ARC. Current PVD techniques are unable to reliably combine low refractive index surfaces near or adjacent to hydrophobic capping layers. Embodiments as disclosed herein provide PVD techniques having a robust, low refractive index outer layer (e.g., magnesium fluoride) compatible with functional coatings such as a hydrophobic layer. In some embodiments, methods as disclosed herein achieve outer layer coatings with a refractive index, n<1.10.

In some embodiments, adhesion to a functional layer such as a hydrophobic layer is provided by co-depositing an oxide layer (e.g., silica) that promotes chemical adhesion of the hydrophobic layer during the last 10 nm or so of an outer, low-n layer (e.g., magnesium fluoride). In some embodiments, adhesion to a functional layer may include modifying the ARC design to include a thin layer on the outer portion of the outer layer that promotes chemical adhesion to the hydrophobic layer.

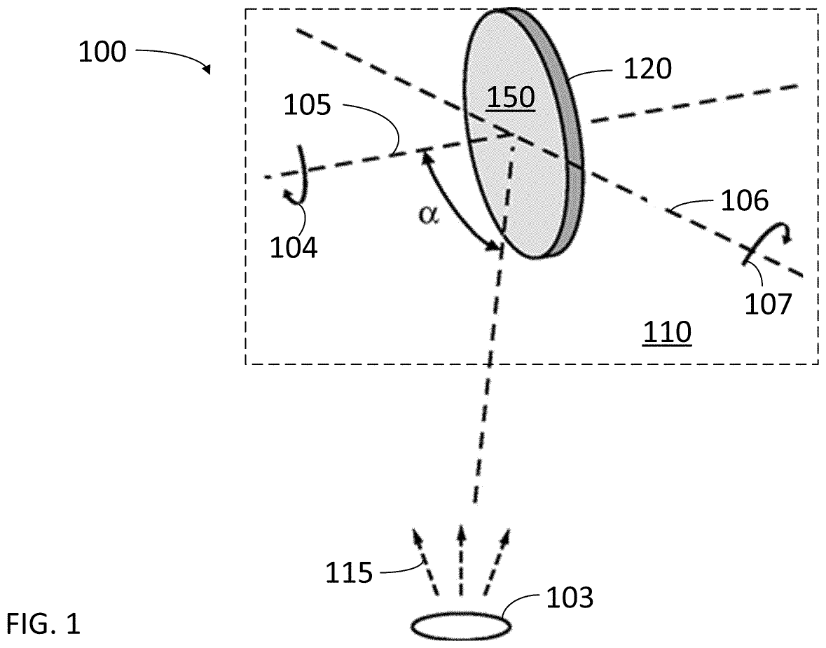

FIG. 1 illustrates a physical vapor deposition (PVD) 100 configured for coating low index of refraction dielectric layers for low reflectance at high angle of incidence on arbitrary optical surfaces, including relevant parameters, according to some embodiments. A rotatable mount 110 supports at least one substrate 120 including a multilayer stack of dielectric layers 150 having alternating high/low index of refraction and is exposed to a deposition source (e.g., a vapor source). Substrate 120 performs a rotation 104 about a substantially normal axis (roll axis 105), forming an impinging angle 107 (a), with a general direction of the molecules 115 of source material coming from a vapor source 103. Impinging angle 107, a, is defined as a tilt of the substrate about a horizontal axis 106 that is perpendicular to normal axis 105 and a general direction of the molecules of source material 103, forming a diameter of substrate 120. In some embodiments, substrate 120 may be coupled to a thermal source that maintains stack 150 at a desired temperature while the deposition takes place.

In some embodiments, substrate 120 is in planetary rotation about vapor source 103, mounted on a rotatable rigging in PVD chamber 100. In some embodiments, rotatable mount 110 includes independent motor control of pitch, yaw, and roll axes. In some embodiments, the substrate is maintained facing the vapor source at a fixed oblique angle, a. In some embodiments, the motor control is based on modeling and simulation of sample rotation including input parameters such as chamber design, dome design, and planetary rotation speed, which may be adjusted via software simulation. In some embodiments, the motor control may include feedback signals from multiple inertial measurement units (IMUs including gimbals and accelerometers), disposed on different mechanical components of a rotatable rigging in the PVD chamber.

The vapor source may include the material for deposition on the substrate (e.g., in bulk, solid phase) and may be configured to apply energy to evaporate a portion of the material (e.g., vacuum evaporation, and the like). The energy applied to evaporate the material may be heat, a plasma-induced ion bombardment (e.g., sputtering), an ion beam or an electron beam directed to the material, and the like.

Additionally, the chamber may include a background gas (e.g., typically a heavy, inert gas such as Argon) to control the mean-free path and transfer energy of the source material towards the multilayer stack. For example, by increasing the pressure of the background gas, the mean free path of the source material molecules is shortened, and the transfer energy of the molecules at the multilayer stack is reduced. This may tend to create a non-uniform, porous layer of dielectric material, which may be desirable to reduce the index of refraction of the deposited dielectric layer relative to the bulk index of refraction of the material forming the dielectric layer.

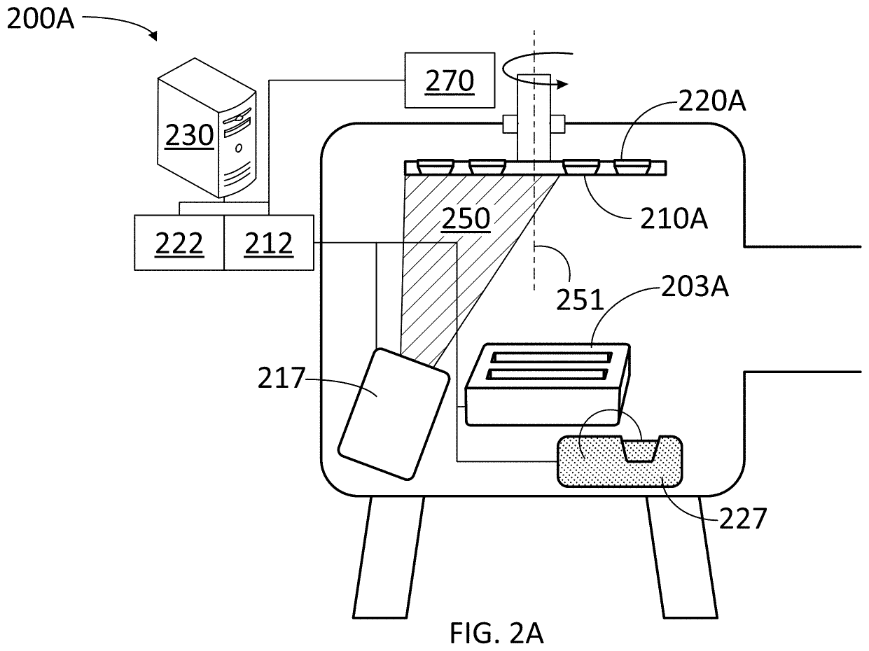

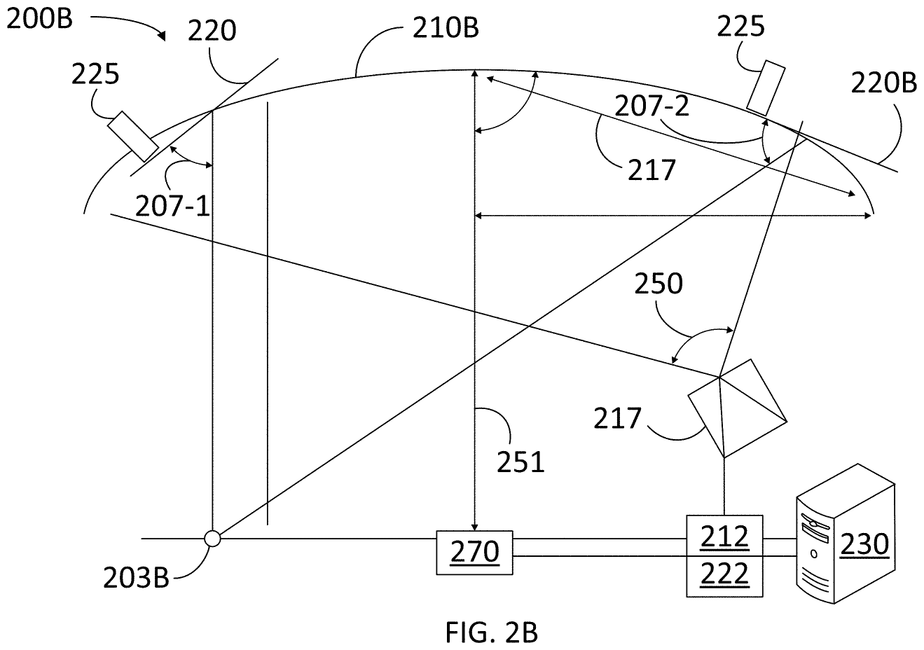

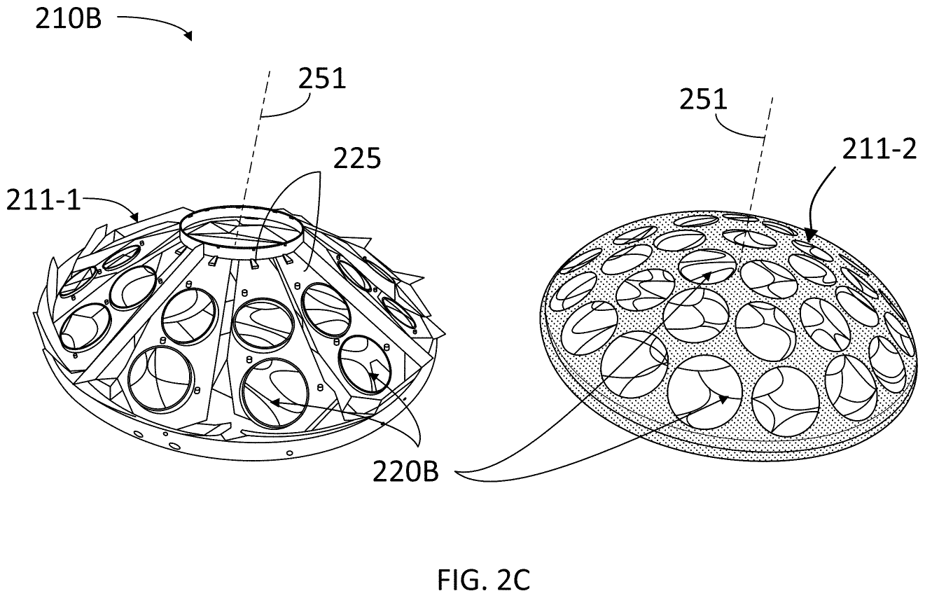

FIGS. 2A-2C illustrate PVD chambers 200A and 200B (hereinafter, collectively referred to as “chambers 200”) configured for providing low index of refraction optical coatings on arbitrary optical surfaces, according to some embodiments. These coatings also enable low reflectance at high angle of incidence on optical surfaces typically used for AR/VR applications. Material sources 203A and 203B (hereinafter, collectively referred to as “material sources 203”) provide source material for deposition onto substrate panels 220A and 220B (collectively referred to, hereinafter, as “substrate panels 220”), mounted on rotatable mounts 210A and 210B (hereinafter, collectively referred to as “rotatable mounts 210”). Rotatable mounts 210 rotate about a central axis 251.

In some embodiments, PVD chambers 200 may include an ion source 217 configured to direct heavy ions onto the optical substrates in substrate panels 220. The heavy ion bombardment produces a high impact momentum transfer to the substrate which in turn results in a more irregular covering (e.g., higher porosity) of the dielectric layers by the source molecules from vapor source 203. As can be seen, the ion plume 250 may have a wide angle of scattering, and may be controllable in spread and directionality, as desired.

PVD chamber 200A includes an electron ion source 227 configured to impinge on material source 203A and excite source molecules to travel and deposit onto substrate panels 220.

In PVD chamber 200B, material source 203B is excited via heating and the ample molecules are evaporatively transferred onto substrate panels 220. In some embodiments, material source 203B is somewhat offset from central axis 251 of a rotatable mount 210. Rotatable mount 210A may include multiple substrate panels 220, each having a motorized gimbal fixture 225. Gimbal fixtures 225 are configured to tilt each of substrate panels 220 as rotatable mount 210 rotates around the vapor source 203, so as to keep the angles of deposition 207-1 and 207-2 (hereinafter, collectively referred to as “incident angles 207”) about the same, or almost constant, over an entire rotation cycle. While angles 207-1 and 207-2 are shown for two diametrically opposed positions of substrate panel 220, for different positions of rotatable mount 210 around a cycle, incident angles 207 will use a different adjustment from gimbal fixture 225.

A computer 230 may include or be coupled with a memory 222 and a processor 212. Memory 222 stores instructions which, when executed by processor 212, cause PVD chambers 200 to coat a multilayer dielectric stack on substrate panels 220, as disclosed herein. For example, processor 212 may include one or more controllers to regulate a motor 270 to move rotatable mounts 210 around central axis 251. Processor 212 may control the operation of gimbal fixtures 225 in coordination with the movement of rotatable mounts 210. The operation of ion source 217 and electron source 227, and also the heating of material source 203A, when desired, may be controlled by processor 212.

FIG. 2C illustrates a perspective view of rotatable mount 210B configured to support multiple substrate panels 220B in PVD chamber 200B, according to some embodiments. Rotatable mount may include an inner core 211-1 and an outer core 211-2 (hereinafter, collectively referred to as “rotatable cores 211”). Each of substrate panels 220B may include motorized gimbal fixtures 225. Motorized gimbal fixtures 225 balance a tilt angle of each of substrate panels 220B as rotatable mount 210 rotates about a central axis 251.

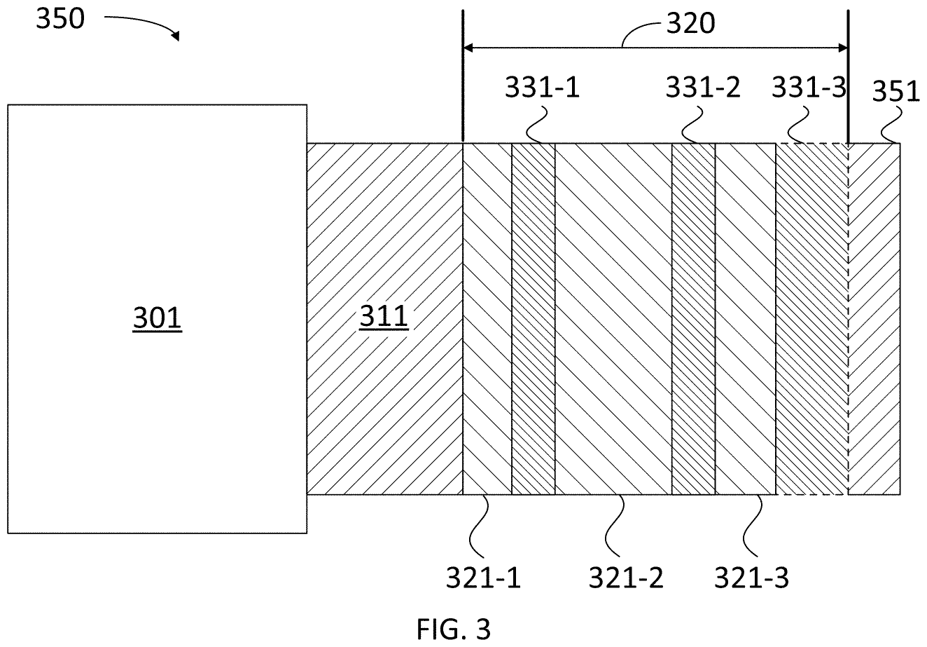

FIG. 3 illustrates a cross section of a multilayer stack 350 of dielectric layers having alternating high/low index of refraction, according to some embodiments. A substrate 301 supports a hard coat layer 311 followed by alternative stack 320. Substrate 301 may have an arbitrary shape (not necessarily planar), and include any moldable material, such as glass or plastic. In some embodiments, substrate 301 may include a high degree of curvature, as some optical surfaces may be used for high NA optics, as desirable for AR/VR environments. Alternative stack 320A includes alternating layers 321-1, 321-2, and 321-3 (hereinafter, collectively referred to as “high-n layers 321”) and low-n layers 331-1, 331-2, and 331-3 (hereinafter, collectively referred to as “low-n layers 331”). In some embodiments, high-n layers 321 may include titanium oxide (Ti₃O₅, high n), and low-n layers 331 may include silicon oxide (e.g., silica, SiO₂, low n). In some embodiments, a hydrophobic layer 351 completes stack 350 on an outer face. Subjacent to outer hydrophobic layer 351, some embodiments may include a low-n outer layer 331-3. In some embodiments, low-n outer layer 331-3 may include a porous silica layer, a magnesium fluoride layer, a porous magnesium fluoride layer, or any combination of the above. The thickness of each one of the alternating layers in alternative stack 320A with high/low n may be different and may be varied according to a desired spectral/angular performance of a filter formed by multilayer stack 350.

The refractive index, n, of outer layer 331-3 in multilayer stack 350, relative to the refractive index of air (1.0), is a key factor to achieve low reflectivity at higher AOIs and across the visible wavelength range. Embodiments as disclosed herein include improved ARC designs with magnesium fluoride (n=1.38) in outer layer 331-3, instead of silica (n=1.46). In some embodiments, ARC performance can be dramatically improved when the refractive index on outer layer 331-3 approaches n=1.02.

In some embodiments, multilayer stack 350 includes a low reflectivity from about 0 (e.g., normal incidence) to ±60° angle of incident for ultra-violet (UV) to near-infrared (NIR) wavelength ranges, when the refractive index, n, of outer dielectric layer 331-3 in the relevant wavelength range has a value between about n=1.02 and about n=1.40. For example, in some embodiments, outer layer 331-2 in multilayer dielectric stack 350 is a magnesium fluoride layer with improved robustness, durability, and reliability. To achieve this, in some embodiments, a magnesium fluoride coating as disclosed herein includes ion augmented deposition. In some embodiments, a durable magnesium fluoride layer 331-3 may be deposited on a plastic substrate 301 (e.g., plastic).

In some embodiments, outer layer 331-3 is a porous layer having a low n, which may include any material other than magnesium fluoride, such as silica and the like. To deposit a porous layer of material, the PVD chamber may be configured to operate at a high chamber pressure (e.g., high background gas pressure). In some embodiments, a low-n porous layer may include a nano-porous structure having voids of fluoride, oxide, nitrides, or other dielectrics, leading to a refractive index of about n<1.30. In some embodiments, a nano-porous structured layer as illustrated is formed with incoming deposition flux at an oblique angle relative to the sample such that a non-continuous columnar structure is formed.

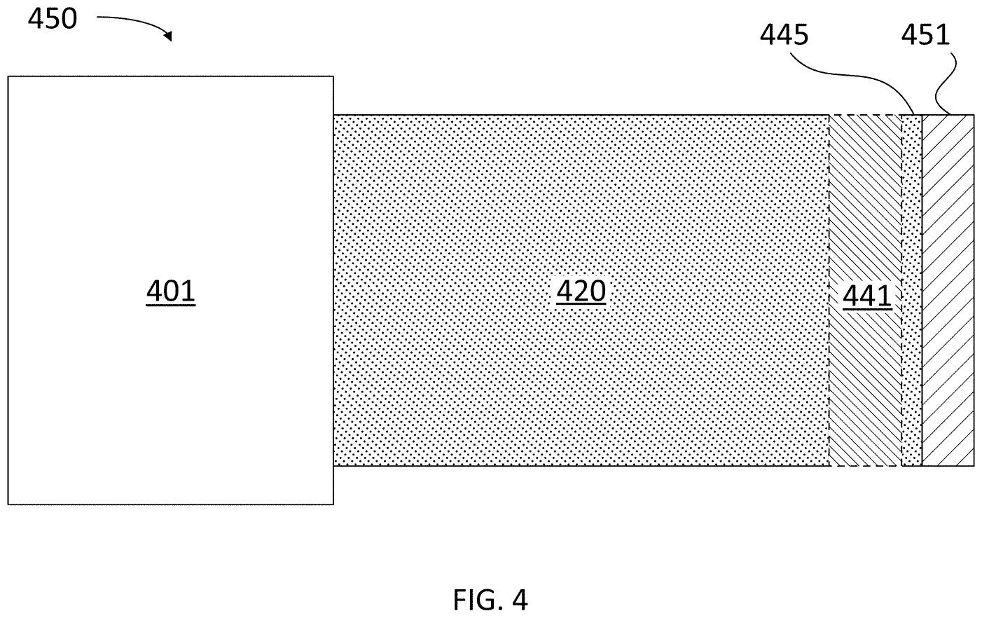

FIG. 4 illustrates a cross section of multilayer stack 450 (hereinafter, collectively referred to as “multilayer stacks 450”) including a substrate 401 adjacent to an alternating stack 420, according to some embodiments. A low-n layer 441 may include a material having lower index of refraction in the bulk than, for example, silica (e.g., magnesium fluoride). Low-n layer 441 (e.g., magnesium fluoride) is separated from a hydrophobic layer 451 by a blend interface layer 445, according to some embodiments. Interface layer 445, adjacent to the multilayer stack 420, securely supports hydrophobic layer 451. In some embodiments, low-n layer 441 may include a magnesium fluoride layer, a porous layer, or a combination thereof. In some embodiments, interface layer 445 is formed by gradually reducing an amount of the low refractive index layer of material and gradually increasing an amount of a hydrophobic compatible material until completion of interface layer 445. For example, in some embodiments, interface layer 445 may be composed of magnesium fluoride and silica, wherein the amount of magnesium fluoride on the side adjacent to outer layer 441 is greater than the amount of silica. The composition of magnesium fluoride and silica may vary towards the side of interface layer 445 facing hydrophobic layer 451. Accordingly, the composition of silica increases towards the side of interface layer 445 adjacent to hydrophobic layer 451.

In some embodiments, interface layer 445 may be obtained by simultaneously using two different material sources in a PVD chamber as disclosed herein (e.g., PVD chamber 100), and varying the intensity of the vapor emissions from either source, accordingly.

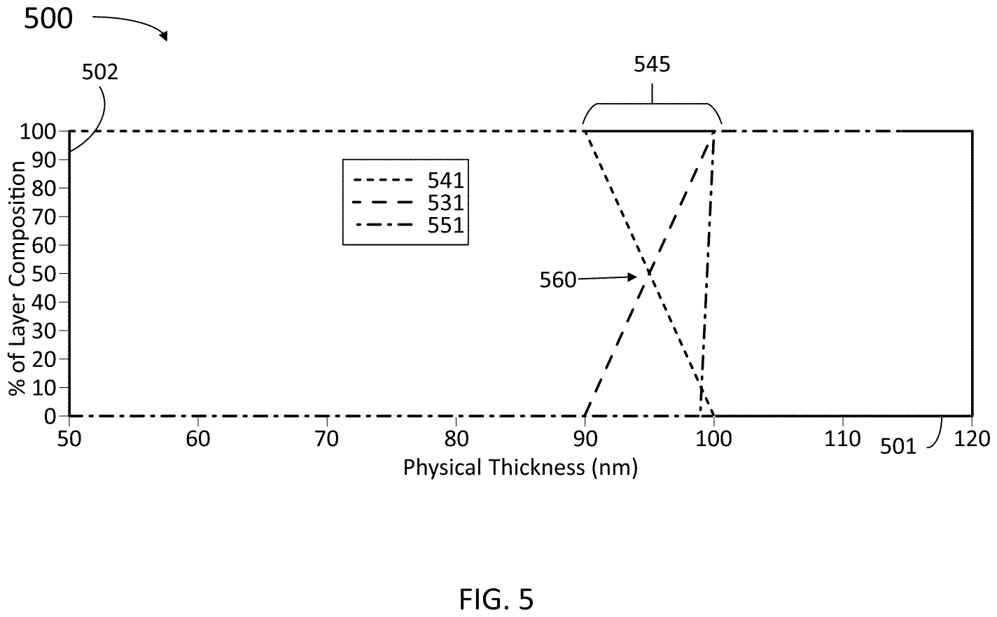

FIG. 5 illustrates a composition plot 500 of an interface layer 545 in a multilayer stack, according to some embodiments. Plot 500 includes a physical thickness 501 (in nanometers, nm) in the abscissae, and a percent layer composition 502 in the ordinates. While the figure illustrates a linear decrease in a proportion of magnesium fluoride curve 541 as the blend interface layer grows from an outer layer (left, cf. outer layer 331-3) to the hydrophobic layer curve 551 (right, c.f., hydrophobic layers 351 and 451), some embodiments may show a different profile for the decrease of curve 541. Likewise, while the figure illustrates a linear increase in a proportion 531 of silica in interface layer 545 towards a hydrophobic layer, some embodiments may show a different profile for the increase in proportion 531. A cross-over point 560 indicates a layer thickness where the proportion of silica surpasses that of magnesium fluoride, thereby providing a solid substrate to the hydrophobic layer.

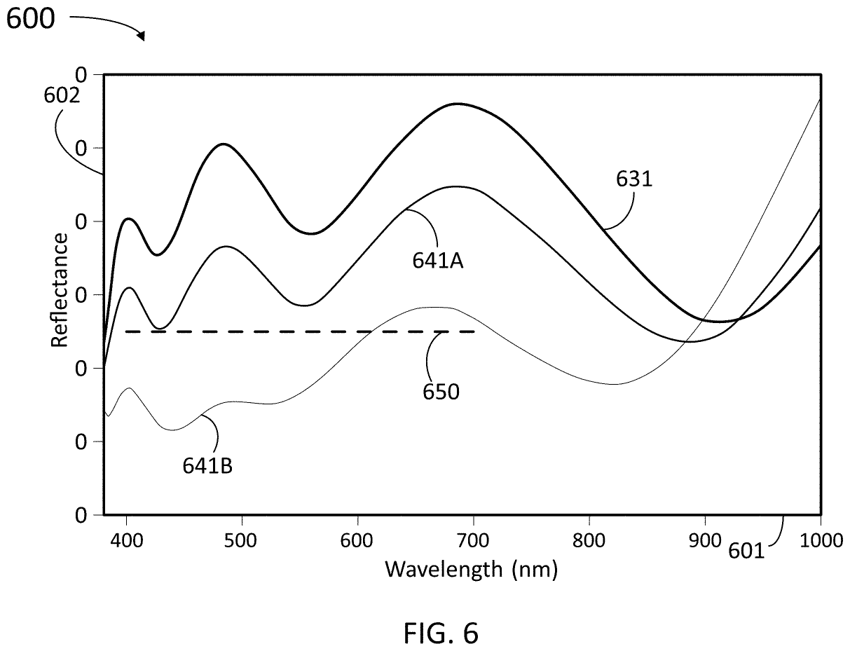

FIG. 6 illustrates a reflectance plot 600 at a wide angle of incidence (up to 65°) for different dielectric materials, including a low-density MgF₂ layer, according to some embodiments. Plot 600 includes abscissae 601 as wavelength (in nanometers, nm), and reflectance 602 as the ordinates. A curve 631 illustrates a dielectric layer formed with silica (SiO₂) at a packing density of 1.0 (no porosity), having an average bulk index of refraction of ˜n=1.46. A curve 641A illustrates a dielectric layer formed with magnesium fluoride at a packing density of 1.0 (no porosity), having an average bulk index of refraction of ˜n=1.36. A curve 641B illustrates a dielectric layer formed with a porous magnesium fluoride layer at a packing density of 0.92, having an average bulk index of refraction of ˜n=1.25. In some embodiments, it is desirable to have reflectance values below a threshold 650 (e.g., 5%, 4% or even less) for at least a substantive portion of the spectral bandwidth shown.

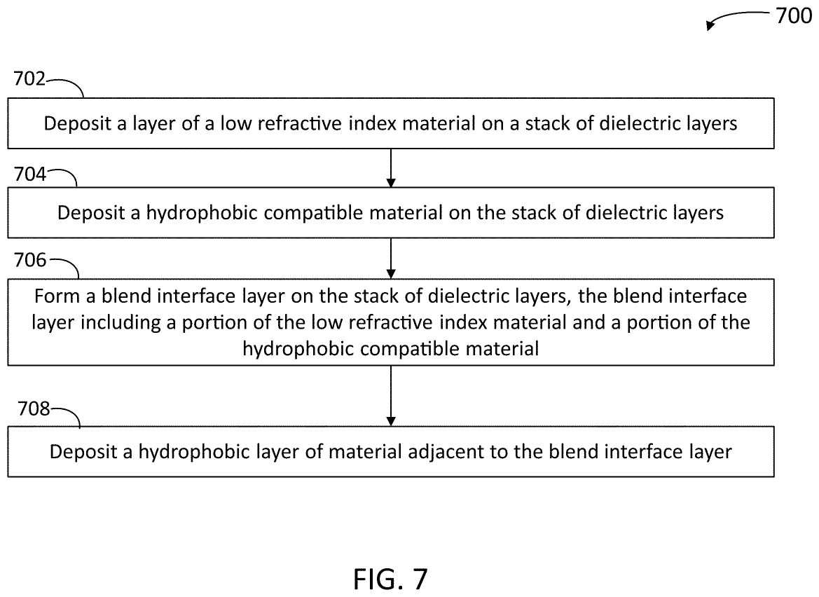

FIG. 7 is a flowchart illustrating steps in a method 700 of forming a multilayer stack of dielectric layers including a layer with a low index of refraction, and capped with a hydrophobic layer of material, according to some embodiments. Method 700 may be performed inside a PVD chamber as disclosed herein (cf. PVD chambers 100 and 200). The chamber may be configured to hold a substrate at a selected distance from a material source in a controlled environment having a background gas (e.g., Argon) at a selected pressure. The substrate may be held at a selected temperature. In some embodiments, at least one or more of the steps in method 700 may be partially or fully performed by a processor executing instructions stored in a memory, as disclosed herein (e.g., processor 212 and memory 222). The processor and the memory may be part of the PVD chamber, or part of a computer communicatively coupled with the PVD chamber (e.g., computer 230). Moreover, methods consistent with the present disclosure may include at least one or more of the steps in method 700 performed alone, or in any combination, simultaneously, quasi-simultaneously, or overlapping in time.

Step 702 includes depositing a layer of a low refractive index material on a stack of dielectric layers. In some embodiments, step 702 includes depositing the layer of low refractive index material adjacent to a layer of high refractive index material on the stack of dielectric layers. In some embodiments, step 702 includes depositing a layer of a material that has a low refractive index in a bulk configuration. In some embodiments, step 702 includes depositing a porous layer of material. In some embodiments, step 702 includes adjusting a pressure or a temperature of a deposition chamber to reduce a density of a layer of material deposited on the stack of dielectric layers. In some embodiments, step 702 includes depositing a layer of magnesium fluoride. In some embodiments, step 702 includes depositing silica on the stack of dielectric layers. In some embodiments, step 702 includes depositing a polymer material adjacent to the blend interface layer.

Step 704 includes depositing a hydrophobic compatible material on the stack of dielectric layers.

Step 706 includes forming a blend interface layer on the stack of dielectric layers, the blend interface layer including a portion of the low refractive index material and a portion of the hydrophobic compatible material. In some embodiments, step 706 includes gradually reducing an amount of the low refractive index layer of material and gradually increasing an amount of the hydrophobic compatible material until completion of the blend interface layer.

Step 708 includes depositing a hydrophobic layer of material adjacent to the blend interface layer.

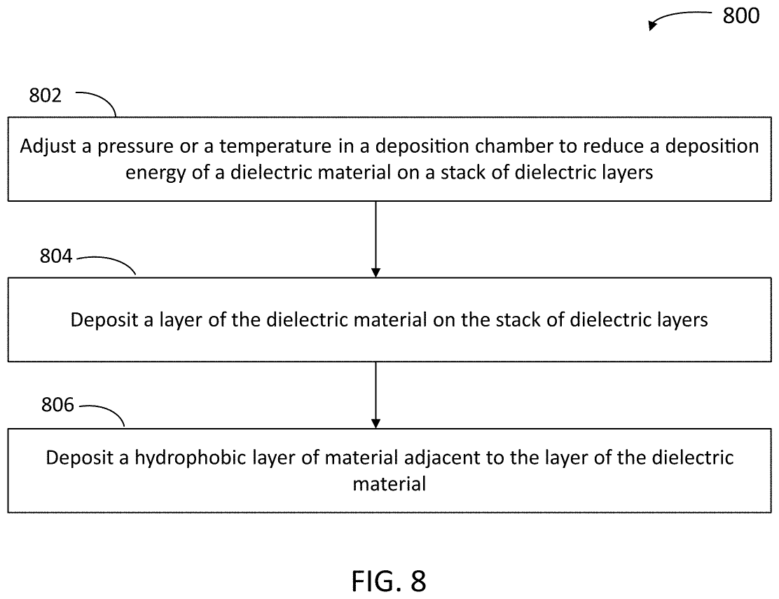

FIG. 8 is a flowchart illustrating steps in a method 800 of forming a multilayer stack of dielectric layers including a layer with a low index of refraction, and capped with a hydrophobic layer of material, according to some embodiments. Method 800 may be performed inside a PVD chamber as disclosed herein. The chamber may be configured to hold a substrate at a selected distance from a material source in a controlled environment having a background gas (e.g., Argon) at a selected pressure. The substrate may be held at a selected temperature. In some embodiments, at least one or more of the steps in method 800 may be partially or fully performed by a processor executing instructions stored in a memory, as disclosed herein (e.g., processor 212 and memory 222). The processor and the memory may be part of the PVD chamber, or part of a computer communicatively coupled with the PVD chamber (e.g., computer 230). Moreover, methods consistent with the present disclosure may include at least one or more of the steps in method 800 performed alone, or in any combination, simultaneously, quasi-simultaneously, or overlapping in time.

Step 802 includes adjusting a pressure or a temperature in a deposition chamber to reduce a deposition energy of a dielectric material on the stack of dielectric layers. In some embodiments, step 802 includes increasing the pressure of the background gas in the deposition chamber to reduce a mean free path of the dielectric material in the deposition chamber below a distance between a material source and the stack of dielectric layers.

Step 804 includes depositing a layer of the dielectric material on the stack of dielectric layers. In some embodiments, step 804 includes depositing a layer of low refractive index material adjacent to a layer of high refractive index material. In some embodiments, step 804 includes depositing a layer of magnesium fluoride on the stack of dielectric layers. In some embodiments, step 804 includes reducing a temperature of a substrate supporting the stack of dielectric layers.

Step 806 includes depositing a hydrophobic layer of material adjacent to the layer of the dielectric material.

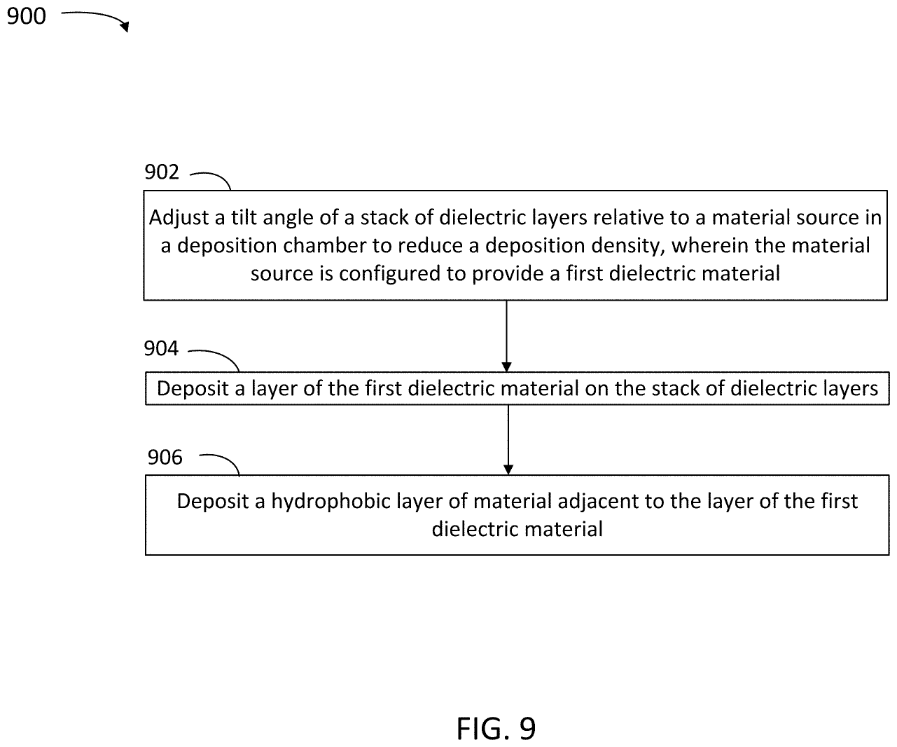

FIG. 9 is a flowchart illustrating steps in a method 900 of forming a multilayer stack of dielectric layers including a layer with a low index of refraction, and capped with a hydrophobic layer of material, according to some embodiments. Method 900 may be performed inside a PVD chamber as disclosed herein. The chamber may be configured to hold a substrate at a selected distance from a material source in a controlled environment having a background gas (e.g., Argon) at a selected pressure. The substrate may be held at a selected temperature.

Step 902 includes adjusting the tilt angle of the stack of dielectric layers relative to a material source in a deposition chamber to reduce a deposition density, wherein the material source is configured to provide a first dielectric material. In some embodiments, step 902 includes increasing an angle of incidence of multiple molecules of the first dielectric material on the stack of dielectric layers. In some embodiments, step 902 includes inducing a self-shadowing effect in a vapor flux of the first dielectric material impinging on the stack of dielectric layers.

Step 904 includes depositing a layer of the first dielectric material on the stack of dielectric layers. In some embodiments, step 904 includes depositing a layer of low refractive index material adjacent to a layer of high refractive index material. In some embodiments, step 904 includes depositing a layer of magnesium fluoride on the stack of dielectric layers. In some embodiments, step 904 includes depositing a layer of silica on the stack of dielectric layers. In some embodiments, at least one or more of the steps in method 900 may be partially or fully performed by a processor executing instructions stored in a memory, as disclosed herein (e.g., processor 212 and memory 222). The processor and the memory may be part of the PVD chamber, or part of a computer communicatively coupled with the PVD chamber (e.g., computer 230). Moreover, methods consistent with the present disclosure may include at least one or more of the steps in method 900 performed alone, or in any combination, simultaneously, quasi-simultaneously, or overlapping in time.

Step 906 includes depositing a hydrophobic layer of material adjacent to the layer of the first dielectric material.

The subject technology is illustrated, for example, according to various aspects described below. Various examples of aspects of the subject technology are described as numbered claims. The claims are provided as examples, and do not limit the subject technology.

In one aspect, a method may be an operation, an instruction, or a function and vice versa. In one aspect, a clause may be amended to include some or all of the words (e.g., instructions, operations, functions, or components) recited in other one or more clauses, one or more words, one or more sentences, one or more phrases, one or more paragraphs, and/or one or more clauses.

### Hardware Overview

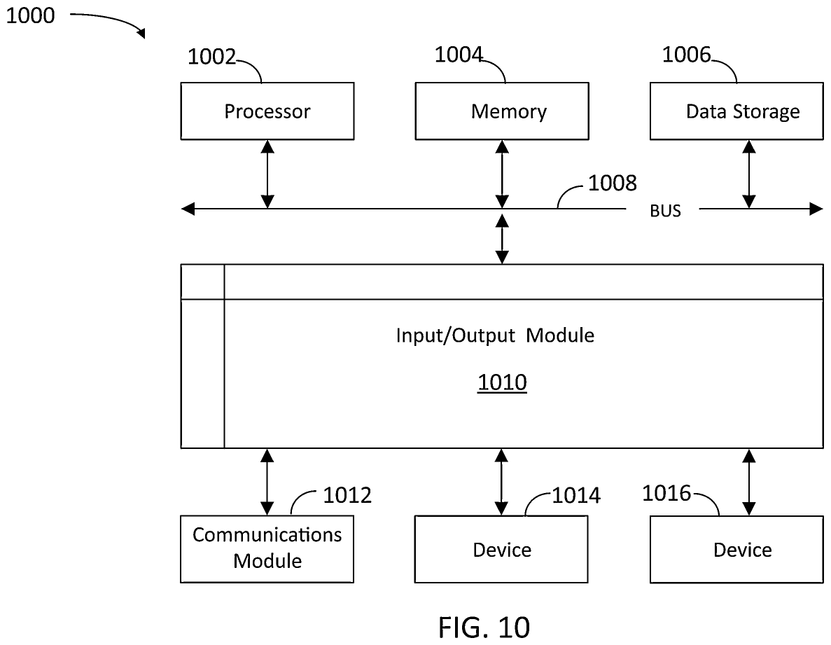

FIG. 10 is a block diagram illustrating an exemplary computer system with which PVD chambers 100 and 200, and methods 700-900 can be implemented, according to some embodiments. In certain aspects, computer system 1000 may be implemented using hardware or a combination of software and hardware, either in a dedicated server, or integrated into another entity, or distributed across multiple entities. Computer system 1000 may include a desktop computer, a laptop computer, a tablet, a phablet, a smartphone, a feature phone, a server computer, or otherwise. A server computer may be located remotely in a data center or be stored locally.

Computer system 1000 includes a bus 1008 or other communication mechanism for communicating information, and a processor 1002 (e.g., processor 212) coupled with bus 1008 for processing information. By way of example, the computer system 1000 may be implemented with one or more processors 1002. Processor 1002 may be a general-purpose microprocessor, a microcontroller, a Digital Signal Processor (DSP), an Application Specific Integrated Circuit (ASIC), a Field Programmable Gate Array (FPGA), a Programmable Logic Device (PLD), a controller, a state machine, gated logic, discrete hardware components, or any other suitable entity that can perform calculations or other manipulations of information.

Computer system 1000 can include, in addition to hardware, code that creates an execution environment for the computer program in question, e.g., code that constitutes processor firmware, a protocol stack, a database management system, an operating system, or a combination of one or more of them stored in an included memory 1004 (e.g., memory 222), such as a Random Access Memory (RAM), a flash memory, a Read-Only Memory (ROM), a Programmable Read-Only Memory (PROM), an Erasable PROM (EPROM), registers, a hard disk, a removable disk, a CD-ROM, a DVD, or any other suitable storage device, coupled with bus 1008 for storing information and instructions to be executed by processor 1002. The processor 1002 and the memory 1004 can be supplemented by, or incorporated in, special purpose logic circuitry.

The instructions may be stored in the memory 1004 and implemented in one or more computer program products, e.g., one or more modules of computer program instructions encoded on a computer-readable medium for execution by, or to control the operation of, the computer system 1000, and according to any method well known to those of skill in the art, including, but not limited to, computer languages such as data-oriented languages (e.g., SQL, dBase), system languages (e.g., C, Objective-C, C++, Assembly), architectural languages (e.g., Java, .NET), and application languages (e.g., PHP, Ruby, Perl, Python). Instructions may also be implemented in computer languages such as array languages, aspect-oriented languages, assembly languages, authoring languages, command line interface languages, compiled languages, concurrent languages, curly-bracket languages, dataflow languages, data-structured languages, declarative languages, esoteric languages, extension languages, fourth-generation languages, functional languages, interactive mode languages, interpreted languages, iterative languages, list-based languages, little languages, logic-based languages, machine languages, macro languages, metaprogramming languages, multiparadigm languages, numerical analysis, non-English-based languages, object-oriented class-based languages, object-oriented prototype-based languages, off-side rule languages, procedural languages, reflective languages, rule-based languages, scripting languages, stack-based languages, synchronous languages, syntax handling languages, visual languages, wirth languages, and xml-based languages. Memory 1004 may also be used for storing temporary variable or other intermediate information during execution of instructions to be executed by processor 1002.

A computer program as discussed herein does not necessarily correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, subprograms, or portions of code). A computer program can be deployed to be executed on one computer or on multiple computers that are located at one site or distributed across multiple sites and interconnected by a communication network. The processes and logic flows described in this specification can be performed by one or more programmable processors executing one or more computer programs to perform functions by operating on input data and generating output.

Computer system 1000 further includes a data storage device 1006 such as a magnetic disk or optical disk, coupled with bus 1008 for storing information and instructions. Computer system 1000 may be coupled via input/output module 1010 to various devices. Input/output module 1010 can be any input/output module. Exemplary input/output modules 1010 include data ports such as USB ports. The input/output module 1010 is configured to connect to a communications module 1012. Exemplary communications modules 1012 include networking interface cards, such as Ethernet cards and modems. In certain aspects, input/output module 1010 is configured to connect to a plurality of devices, such as an input device 1014 and/or an output device 1016. Exemplary input devices 1014 include a keyboard and a pointing device, e.g., a mouse or a trackball, by which a consumer can provide input to the computer system 1000. Other kinds of input devices 1014 can be used to provide for interaction with a consumer as well, such as a tactile input device, visual input device, audio input device, or brain-computer interface device. For example, feedback provided to the consumer can be any form of sensory feedback, e.g., visual feedback, auditory feedback, or tactile feedback; and input from the consumer can be received in any form, including acoustic, speech, tactile, or brain wave input. Exemplary output devices 1016 include display devices, such as an LCD (liquid crystal display) monitor, for displaying information to the consumer.

According to one aspect of the present disclosure, PVD chambers 100 or 200 can be implemented, at least partially, using a computer system 1000 in response to processor 1002 executing one or more sequences of one or more instructions contained in memory 1004. Such instructions may be read into memory 1004 from another machine-readable medium, such as data storage device 1006. Execution of the sequences of instructions contained in main memory 1004 causes processor 1002 to perform the process steps described herein. One or more processors in a multi-processing arrangement may also be employed to execute the sequences of instructions contained in memory 1004. In alternative aspects, hard-wired circuitry may be used in place of or in combination with software instructions to implement various aspects of the present disclosure. Thus, aspects of the present disclosure are not limited to any specific combination of hardware circuitry and software.

Various aspects of the subject matter described in this specification can be implemented in a computing system that includes a back end component, e.g., a data server, or that includes a middleware component, e.g., an application server, or that includes a front end component, e.g., a client computer having a graphical consumer interface or a Web browser through which a consumer can interact with an implementation of the subject matter described in this specification, or any combination of one or more such back end, middleware, or front end components. The components of the system can be interconnected by any form or medium of digital data communication, e.g., a communication network. The communication network (e.g., network 150) can include, for example, any one or more of a LAN, a WAN, the Internet, and the like. Further, the communication network can include, but is not limited to, for example, any one or more of the following network topologies, including a bus network, a star network, a ring network, a mesh network, a star-bus network, tree or hierarchical network, or the like. The communications modules can be, for example, modems or Ethernet cards.

Computer system 1000 can include clients and servers. A client and server are generally remote from each other and typically interact through a communication network. The relationship of client and server arises by virtue of computer programs running on the respective computers and having a client-server relationship to each other. Computer system 1000 can be, for example, and without limitation, a desktop computer, laptop computer, or tablet computer. Computer system 1000 can also be embedded in another device, for example, and without limitation, a mobile telephone, a PDA, a mobile audio player, a Global Positioning System (GPS) receiver, a video game console, and/or a television set top box.

The term “machine-readable storage medium” or “computer-readable medium” as used herein refers to any medium or media that participates in providing instructions to processor 1002 for execution. Such a medium may take many forms, including, but not limited to, non-volatile media, volatile media, and transmission media. Non-volatile media include, for example, optical or magnetic disks, such as data storage device 1006. Volatile media include dynamic memory, such as memory 1004. Transmission media include coaxial cables, copper wire, and fiber optics, including the wires forming bus 1008. Common forms of machine-readable media include, for example, floppy disk, a flexible disk, hard disk, magnetic tape, any other magnetic medium, a CD-ROM, DVD, any other optical medium, punch cards, paper tape, any other physical medium with patterns of holes, a RAM, a PROM, an EPROM, a FLASH EPROM, any other memory chip or cartridge, or any other medium from which a computer can read. The machine-readable storage medium can be a machine-readable storage device, a machine-readable storage substrate, a memory device, a composition of matter affecting a machine-readable propagated signal, or a combination of one or more of them.

To illustrate the interchangeability of hardware and software, items such as the various illustrative blocks, modules, components, methods, operations, instructions, and algorithms have been described generally in terms of their functionality. Whether such functionality is implemented as hardware, software, or a combination of hardware and software depends upon the particular application and design constraints imposed on the overall system. Skilled artisans may implement the described functionality in varying ways for each particular application.

As used herein, the phrase “at least one of” preceding a series of items, with the terms “and” or “or” to separate any of the items, modifies the list as a whole, rather than each member of the list (e.g., each item). The phrase “at least one of” does not require selection of at least one item; rather, the phrase allows a meaning that includes at least one of any one of the items, and/or at least one of any combination of the items, and/or at least one of each of the items. By way of example, the phrases “at least one of A, B, and C” or “at least one of A, B, or C” each refer to only A, only B, or only C; any combination of A, B, and C; and/or at least one of each of A, B, and C.

The word “exemplary” is used herein to mean “serving as an example, instance, or illustration.” Any embodiment described herein as “exemplary” is not necessarily to be construed as preferred or advantageous over other embodiments. Phrases such as an aspect, the aspect, another aspect, some aspects, one or more aspects, an implementation, the implementation, another implementation, some implementations, one or more implementations, an embodiment, the embodiment, another embodiment, some embodiments, one or more embodiments, a configuration, the configuration, another configuration, some configurations, one or more configurations, the subject technology, the disclosure, the present disclosure, other variations thereof and alike are for convenience and do not imply that a disclosure relating to such phrase(s) is essential to the subject technology or that such disclosure applies to all configurations of the subject technology. A disclosure relating to such phrase(s) may apply to all configurations, or one or more configurations. A disclosure relating to such phrase(s) may provide one or more examples. A phrase such as an aspect or some aspects may refer to one or more aspects and vice versa, and this applies similarly to other foregoing phrases.

A reference to an element in the singular is not intended to mean “one and only one” unless specifically stated, but rather “one or more.” Pronouns in the masculine (e.g., his) include the feminine and neuter gender (e.g., her and its) and vice versa. The term “some” refers to one or more. Underlined and/or italicized headings and subheadings are used for convenience only, do not limit the subject technology, and are not referred to in connection with the interpretation of the description of the subject technology. Relational terms such as first and second and the like may be used to distinguish one entity or action from another without necessarily requiring or implying any actual such relationship or order between such entities or actions. All structural and functional equivalents to the elements of the various configurations described throughout this disclosure that are known or later come to be known to those of ordinary skill in the art are expressly incorporated herein by reference and intended to be encompassed by the subject technology. Moreover, nothing disclosed herein is intended to be dedicated to the public, regardless of whether such disclosure is explicitly recited in the above description. No clause element is to be construed under the provisions of 35 U.S.C. § 112, sixth paragraph, unless the element is expressly recited using the phrase “means for” or, in the case of a method clause, the element is recited using the phrase “step for.”

While this specification contains many specifics, these should not be construed as limitations on the scope of what may be described, but rather as descriptions of particular implementations of the subject matter. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially described as such, one or more features from a described combination can in some cases be excised from the combination, and the described combination may be directed to a subcombination or variation of a subcombination.

The subject matter of this specification has been described in terms of particular aspects, but other aspects can be implemented and are within the scope of the following clauses. For example, while operations are depicted in the drawings in a particular order, this should not be understood as requiring that such operations be performed in the particular order shown or in sequential order, or that all illustrated operations be performed, to achieve desirable results. The actions recited in the clauses can be performed in a different order and still achieve desirable results. As one example, the processes depicted in the accompanying figures do not necessarily require the particular order shown, or sequential order, to achieve desirable results. In certain circumstances, multitasking and parallel processing may be advantageous. Moreover, the separation of various system components in the aspects described above should not be understood as requiring such separation in all aspects, and it should be understood that the described program components and systems can generally be integrated together in a single software product or packaged into multiple software products.

The title, background, brief description of the drawings, abstract, and drawings are hereby incorporated into the disclosure and are provided as illustrative examples of the disclosure, not as restrictive descriptions. It is submitted with the understanding that they will not be used to limit the scope or meaning of the clauses. In addition, in the detailed description, it can be seen that the description provides illustrative examples and the various features are grouped together in various implementations for the purpose of streamlining the disclosure. The method of disclosure is not to be interpreted as reflecting an intention that the described subject matter requires more features than are expressly recited in each clause. Rather, as the clauses reflect, inventive subject matter lies in less than all features of a single disclosed configuration or operation. The clauses are hereby incorporated into the detailed description, with each clause standing on its own as a separately described subject matter.

The clauses are not intended to be limited to the aspects described herein, but are to be accorded the full scope consistent with the language clauses and to encompass all legal equivalents. Notwithstanding, none of the clauses are intended to embrace subject matter that fails to satisfy the requirements of the applicable patent law, nor should they be interpreted in such a way.

What is claimed is:

1. A method, comprising:
depositing a low refractive index layer of material on a stack of dielectric layers;
depositing a hydrophobic compatible material on the stack of dielectric layers;
forming a blend interface layer on the stack of dielectric layers, the blend interface layer including a portion of the low refractive index layer of material and a portion of the hydrophobic compatible material; and
depositing a hydrophobic layer of material adjacent to the blend interface layer.

2. The method of claim 1, wherein depositing a low refractive index layer of material on a stack of dielectric layers comprises depositing the layer of low refractive index material adjacent to a layer of high refractive index material on the stack of dielectric layers.

3. The method of claim 1, wherein depositing a low refractive index layer of material comprises depositing a layer of a material that has a low refractive index in a bulk configuration.

4. The method of claim 1, wherein depositing a low refractive index layer of material comprises depositing a porous layer of material.

5. The method of claim 1, wherein depositing a low refractive index layer of material comprises adjusting a pressure or a temperature of a deposition chamber to reduce a density of a layer of material deposited on the stack of dielectric layers.

6. The method of claim 1, wherein depositing a layer of a low refractive index material on a stack of dielectric layers comprises depositing a layer of magnesium fluoride.

7. The method of claim 1, wherein depositing a hydrophobic compatible material on the stack of dielectric layers comprises depositing silica on the stack of dielectric layers.

8. The method of claim 1, wherein depositing a hydrophobic layer of material adjacent to the blend interface layer comprises depositing a polymer material adjacent to the blend interface layer.

9. The method of claim 1, wherein forming a blend interface layer comprises gradually reducing an amount of the low refractive index layer of material and gradually increasing an amount of the hydrophobic compatible material until completion of the blend interface layer.

10. A method, comprising:
adjusting a pressure of a background gas in a deposition chamber to reduce a deposition energy of a dielectric material on a stack of dielectric layers;
depositing a layer of the dielectric material on the stack of dielectric layers; and
depositing a hydrophobic layer of material adjacent to the layer of the dielectric material.

11. The method of claim 10, wherein adjusting a pressure of the background gas in a deposition chamber comprises increasing the pressure of the background gas in the deposition chamber to reduce a mean free path of the dielectric material in the deposition chamber below a distance between a material source and the stack of dielectric layers.

12. The method of claim 10, wherein depositing a layer of the dielectric material on the stack of dielectric layers comprises depositing a layer of low refractive index material adjacent to a layer of high refractive index material.

13. The method of claim 10, wherein depositing a layer of the dielectric material on the stack of dielectric layers comprises depositing a layer of magnesium fluoride on the stack of dielectric layers.

14. The method of claim 10, wherein depositing a layer of the dielectric material on the stack of dielectric layers comprises reducing a temperature of a substrate supporting the stack of dielectric layers.

15. A method, comprising:
adjusting a tilt angle of a stack of dielectric layers relative to a material source in a deposition chamber to reduce a deposition density, wherein the material source is configured to provide a first dielectric material;
depositing a layer of the first dielectric material on the stack of dielectric layers; and
depositing a hydrophobic layer of material adjacent to the layer of the first dielectric material.

16. The method of claim 15, wherein adjusting a tilt angle of a stack of dielectric layers relative to a material source comprises increasing an angle of incidence of multiple molecules of the first dielectric material on the stack of dielectric layers.

17. The method of claim 15, wherein adjusting a tilt angle of a stack of dielectric layers relative to a material source comprises inducing a self-shadowing effect in a vapor flux of the first dielectric material impinging on the stack of dielectric layers.

18. The method of claim 15, wherein depositing a layer of the first dielectric material on the stack of dielectric layers comprises depositing a layer of low refractive index material adjacent to a layer of high refractive index material.

19. The method of claim 15, wherein depositing a layer of the first dielectric material on the stack of dielectric layers comprises depositing a layer of magnesium fluoride on the stack of dielectric layers.

20. The method of claim 15, wherein depositing a layer of the first dielectric material on the stack of dielectric layers comprises depositing a layer of silica on the stack of dielectric layers.
